(19) United States
(12) Patent Application Publication
(10) Pub. No.: US 2024/0430995 A1
(43) Pub. Date: Dec. 26, 2024

(54) MICROWAVE OVEN WITH RADIANT ENERGY HEATING ELEMENT

(71) Applicant: Revolution Cooking, LLC, Woburn, MA (US)

(72) Inventors: Philip C. Carbone, North Reading, MA (US); Cody O'Sullivan, London (GB); Nicholas McKinnon, Boston, MA (US); Anna Cheimets, Medford, MA (US); Ryan O'Donnell, Ipswich, MA (US); Elizabeth Gillis, Lowell, MA (US); Peter J. Loftus, Somerville, MA (US)

(73) Assignee: Revolution Cooking, LLC, Woburn, MA (US)

(21) Appl. No.: 18/824,979

(22) Filed: Sep. 5, 2024

Related U.S. Application Data
(63) Continuation of application No. PCT/US2023/014606, filed on Mar. 6, 2023.
(60) Provisional application No. 63/317,658, filed on Mar. 8, 2022.

(51) Int. Cl. H05B 6/64; F24C 7/04; H05B 3/44

(52) U.S. Cl. CPC H05B 6/6482; F24C 7/043; H05B 3/44

(57) ABSTRACT

A heating arrangement for a cooking appliance, such as a toaster or oven. Heating elements can be exposed in a cavity of the appliance and can have a shield that permits infrared energy to pass but blocks microwaves and/or provides physical support for internal components such as a quartz tube or resistance element. The shield can be grounded to one or more cavity walls by grounding elements that engage with the shield and a portion of the cavity wall. The heating element can emit a greater amount of infrared radiation in one direction than an opposite direction, e.g., due to a convex or other shape of the resistance element. Sets of heating elements can be controlled so that a second element begins to emit visible light at a same time that a first element stops emitting visible light. Convection air can be directed at one or more heating elements, which diffuse the air flow or otherwise prevent flow of air directly to food in the cavity.

### BACKGROUND

Various appliances are available for cooking or otherwise heating food. An oven, for example, is often used for cooking food at lower to moderate temperatures for fairly long periods of time. A microwave oven, on the other hand, utilizes microwave energy and can heat at least some foods more rapidly. In some cases, microwave ovens also include one or more radiant heating elements.

### SUMMARY

In some embodiments, an electrical resistance heating element is provided that is configured for use in a microwave oven, e.g., in which the heating element is located in a cooking cavity and exposed to microwaves around its outer surface. In some cases, the heating element can be configured to help prevent microwaves from exiting the cooking cavity, e.g., via a conductive element of the heating element that emits infrared radiation. In some examples, the heating element includes a tube having a wall defining an inner space, an outer surface and a length extending along a longitudinal axis from a first end of the wall to a second end of the wall. The wall can be configured to permit infrared radiation to pass through the wall from the inner space to the outer surface, e.g., the tube can be made of a quartz or other material that is relatively transparent to infrared radiation. A resistance element can extend in the inner space between the first and second ends of the tube wall and can include a circuit configured to emit infrared radiation in response to an electrical current in the resistance element. As an example, the circuit can include a metal or other conductive component that heats in response to electric current in the circuit to emit infrared energy. A shield can extend over the outer surface of the tube with the shield configured to permit infrared radiation to pass through at least a portion of the shield and to prevent microwaves employed in a microwave oven from being incident on the tube. In some cases, the portion of the shield configured to permit infrared radiation to pass is configured to permit 70 to 90% of infrared radiation emitted by the circuit to pass through the shield. By preventing microwaves from being incident on the tube, the shield can help prevent microwaves in the cooking cavity from exiting the cavity via the resistance element.

In some examples, the shield has a tubular shape, e.g., the shield can completely surround the tube. In some embodiments, the shield has a first portion that extends along the length of the tube and is configured to block passage of infrared radiation emitted by the circuit, and a second portion that extends along at least a portion of the length of the tube and is configured to permit infrared radiation emitted by the circuit to pass through the shield. As an example, the first portion of the shield can include a tubular wall section with no openings and the second portion can include a conductive component with a plurality of openings configured to permit infrared radiation to pass through the openings and to block the microwaves from passing through the openings. In some cases, the second portion can include a metal mesh or other conductive component having openings that permit infrared energy to pass but prevent the passage of microwaves through the shield. In some cases, the circuit is configured to emit a greater amount of infrared radiation in a first direction than in a second direction that is opposite the first direction, and the circuit can be configured so that the first direction extends through the second portion of the shield. Thus, the heating element can be configured to emit a greater amount of infrared radiation in a direction in which the shield allows infrared energy to pass. In some examples, the circuit defines a convex shape, e.g., a V-shape, that extends between the first and second ends and that faces in the first direction.

In some cases, the shield is configured to protect the tube from physical impact. The shield can be configured to be electrically grounded to a cavity wall of a microwave oven, e.g., to aid in preventing microwaves from exiting the cooking cavity.

In some embodiments, an electrical resistance heating element can include a tube having a wall defining an inner space, an outer surface and a length extending along a longitudinal axis from a first end of the wall to a second end of the wall. The wall can be configured to permit infrared radiation to pass through the wall from the inner space to the outer surface, e.g., the wall can be made of a quartz material. A resistance element can extend in the inner space between the first and second ends and include a circuit configured to emit infrared radiation in response to an electrical current in the resistance element. In some cases, the circuit can define a convex shape that extends between the first and second ends. In some examples, the convex shape can extend a distance between the first and second ends that is at least 20% of the length of the wall. In some cases, the circuit has a width in a direction perpendicular to the longitudinal axis, and the convex shape can extend a distance that is greater than the width. For example, the convex shape can have a width in the direction perpendicular to the longitudinal axis that is at least 90% of the width of the circuit. In some embodiments, the convex shape faces in a first direction and the circuit is configured to emit a greater amount of infrared radiation in the first direction than in a second direction opposite to the first direction. In some examples, the circuit defines a concave shape that extends between the first and second ends and is opposed to the convex shape. For example, the convex shape can face in a first direction and the concave shape can face in a second direction opposite to the first direction. The circuit can be configured to emit a greater amount of infrared radiation in the first direction than in the second direction. In some cases, the circuit is configured to emit 20% to 30% more infrared radiation in the first direction than in the second direction.

In some examples, a portion of the circuit that defines the convex shape includes a first planar portion arranged at an angle relative to a second planar portion. For example, the portion of the circuit can have a joint between the first and second portions. In some cases, a portion of the circuit that defines the convex shape includes first and second sides that are opposed to each other, each of the first and second sides having a serpentine shape defined by bends connected by legs that each extend between respective bends. In some examples, the legs extend perpendicularly to the longitudinal axis, and the first and second sides can include outer edges defined by bends. In some cases, the convex shape has a V-shape in cross section along a plane perpendicular to the longitudinal axis.

In some embodiments, a shield can extend over the outer surface of the tube, and the shield can be configured to protect the tube from physical impact. For example, a shield can extend over the outer surface of the tube, and the shield can be configured to prevent microwaves employed in a microwave oven from being incident on the tube. In some cases, a shield that extends over the outer surface of the tube has a first portion that extends along the length of the tube and is configured to block passage of infrared radiation emitted by the circuit, and a second portion that extends along at least a portion of the length of the tube and is configured to permit infrared radiation emitted by the circuit to pass through the shield. In some examples, the first and second portions are configured to prevent microwaves employed in a microwave oven from being incident on the tube.

In some embodiments, an electrical resistance heating element includes a tube having a wall defining an inner space, an outer surface and a length extending along a longitudinal axis from a first end of the wall to a second end of the wall. The wall can be configured to permit infrared radiation to pass through the wall from the inner space to the outer surface. A resistance element can extend in the inner space between the first and second ends and include a circuit configured to emit infrared radiation in response to an electrical current in the resistance element. In some cases, the circuit can be configured to emit a greater amount of infrared radiation in a first direction than in a second direction that is opposite the first direction.

In some examples, the circuit is configured to emit 20% to 30% more infrared radiation in the first direction than in the second direction. In some cases, the first and second directions are perpendicular to the longitudinal axis. In some embodiments, the circuit defines a convex shape that extends between the first and second ends and faces in the first direction. For example, the circuit defines a concave shape that extends between the first and second ends and is opposed to the convex shape with the convex shape facing in second direction. In some cases, the convex shape extends a distance between the first and second ends that is at least 20% of the length of the wall. In some embodiments, the circuit has a width in a direction perpendicular to the longitudinal axis, and the convex shape extends a distance along the longitudinal axis that is greater than the width. For example, the convex shape can have a width in the direction perpendicular to the longitudinal axis that is at least 90% of the width of the circuit. In some cases, a portion of the circuit that defines the convex shape includes a first planar portion arranged at an angle relative to a second planar portion, e.g., the circuit can have a joint between the first and second portions. In some examples, a portion of the circuit includes first and second sides that are opposed to each other and has a serpentine shape defined by bends connected by legs that each extend between respective bends. In some cases, the legs extend perpendicularly to the longitudinal axis and the first and second sides can have outer edges defined by bends. In some examples, the circuit has a V-shape in cross section along a plane perpendicular to the longitudinal axis.

In some embodiments, a shield can extend over the outer surface of the tube with the shield configured to protect the tube from physical impact. In some cases, a shield that extends over the outer surface of the tube with the shield configured to prevent microwaves employed in a microwave oven from being incident on the tube. In some examples, a shield that extends over the outer surface of the tube has a first portion that extends along at least a portion of the length of the tube and is configured to permit infrared radiation emitted by the circuit in the first direction to pass through the shield, and a second portion that extends along the length of the tube and is configured to block passage of infrared radiation emitted by the circuit in the second direction. In some cases, the first and second portions are configured to prevent microwaves employed in a microwave oven from being incident on the tube.

In some embodiments, a microwave oven includes a cooking cavity defined by one or more cavity walls configured to receive food to be heated, a microwave supply including a magnetron configured to provide microwaves for introduction into the cooking cavity to heat food in the cavity, and a radiant energy heating element positioned in the cooking cavity for exposure to microwaves in the cooking cavity. The heating element can include a resistance element extending between first and second ends with the resistance element including a circuit configured to emit infrared radiation in response to an electrical current in the resistance element, and a shield that extends around the resistance element. The shield can be configured to permit infrared radiation to pass through at least a portion of the shield and to prevent microwaves from being incident on the resistance element. In some embodiments, the shield can define an outer surface of the heating element. In some cases, the heating element can be configured as described above and elsewhere herein, e.g., to include a tube having a wall defining an inner space in which the resistance element is positioned, an outer surface, and a length extending along a longitudinal axis from a first end of the wall to a second end of the wall. The wall can be configured to permit infrared radiation to pass through the wall from the inner space to the outer surface, e.g., the tube can be a quartz tube, and the shield can extend over the outer surface of the tube. In some cases, the shield can completely surround the tube, e.g., have a tubular shape that extends over the tube of the heating element. In some examples, the shield has a first portion that extends along a length of the resistance element and is configured to block passage of infrared radiation emitted by the circuit, and a second portion that extends along at least a portion of the length of the resistance element and is configured to permit infrared radiation emitted by the circuit to pass through the shield. In some embodiments, the second portion includes a conductive component with a plurality of openings configured to permit infrared radiation to pass through the openings and to block the microwaves from passing through the openings. The shield can be electrically grounded to a cavity wall of the cooking cavity, e.g., by way of one or more grounding contacts connected between the shield and the cavity wall. In some cases, the shield can extend along and be spaced from a cavity wall, e.g., so the entire exterior of the heating element is exposed to microwaves in the cavity.

In some cases, the circuit can be configured to emit a greater amount of infrared radiation in a first direction than in a second direction that is opposite the first direction, and the first direction can extend through the second portion of the shield. For example, the circuit can define a convex shape that extends between the first and second ends and that faces in the first direction.

In some cases, the oven can include multiple components for heating food in the cooking cavity. For example, the microwave supply can include a waveguide to guide microwaves emitted by the magnetron to the cooking cavity. In some cases, the oven can also include a convection element including a fan to move air into the cooking cavity. The convection element can include a duct having one or more ports, and the fan can be configured to move air in the duct to the one or more ports. In some embodiments, the one or more ports can be configured to output moving air that is directed at the heating element, e.g., so the air is diffused or otherwise dispersed by the heating element.

In some embodiments, an electrical resistance heating element includes a resistance element extending between the first and second ends with the resistance element including a circuit configured to emit infrared radiation in response to an electrical current in the resistance element. A shield can extend over the resistance element with the shield configured to permit infrared radiation to pass through at least a portion of the shield and to prevent microwaves employed in a microwave oven from being incident on the resistance element. The shield can define an outer surface of the heating element. A grounding element can be configured to electrically couple with the shield and with a cavity wall of an oven, e.g., to help prevent microwaves from passing through the shield and being incident on the resistance element.

In some cases, the grounding element includes a body and one or more cavity wall contacts that extend from the body. For example, the body can have a circular shape (e.g., a disc shape) and the cavity wall contacts can extend radially outwardly from a periphery of the body. In some cases, the one or more cavity wall contacts each form a tab that is flexible, e.g., which can be bent elastically and/or plastically. In some embodiments, the grounding element includes a body and one or more shield contacts that extend from the body. For example, the body can have an opening (e.g., having an annular or washer shape) and the one or more shield contacts can extend from the opening. In some cases, the one or more shield contacts each form a tab that is flexible, e.g., which can be bent elastically and/or plastically. In some cases, the shield can be configured to fit within an opening of the grounding element to physically and electrically contact with the grounding element. For example, the shield can include one or more tabs that extend from the shield and are configured to fit within the opening of the grounding element. In some cases, the shield includes a plurality of tabs that extend from the shield in a direction along a length of the shield. For example, a support can be provided that includes at least one opening to receive at least one of the plurality of tabs, and a portion of the support can be configured to fit within the opening of the grounding element. In some cases, the support can include a slot to receive and support an end of the resistance element.

In some embodiments, the heating element can include a tube having a wall defining an inner space, an outer surface and a length extending along a longitudinal axis from a first end of the wall to a second end of the wall. The wall can be configured to permit infrared radiation to pass through the wall from the inner space to the outer surface, the resistance element can extend within the inner space, and the shield can extend over the outer surface. In some cases, the shield has a first portion that extends along the length of the tube and is configured to block passage of infrared radiation emitted by the circuit, and a second portion that extends along at least a portion of the length of the tube and is configured to permit infrared radiation emitted by the circuit to pass through the shield. For example, the portion of the shield configured to permit infrared radiation to pass is configured to permit 70 to 90% of infrared radiation emitted by the circuit to pass through the shield.

In some embodiments, an electrical resistance heating element includes a resistance element extending between the first and second ends with the resistance element including a circuit configured to emit infrared radiation in response to an electrical current in the resistance element. A support can include a slot to receive and support the first or second end of the resistance element with the support configured to engage the resistance element to permit the first or second end to move within the slot due to thermal expansion or contraction of the resistance element. For example, the resistance element and the support can be configured such that the resistance element can move longitudinally in the slot but is prevented from rotating in the slot. In some cases, the resistance element defines a convex shape at the first and second ends, and the slot is configured to closely conform to the convex shape. For example, the resistance element can have a V-shape at the first and second ends, and the slot can have a V-shape to receive the first and/or second end. In some cases, the convex shape extends from the first end to the second end, and/or the convex shape can face in a first direction and the circuit can be configured to emit a greater amount of infrared radiation in the first direction than in a second direction opposite to the first direction.

In some embodiments, the heating element can include a tube having a wall defining an inner space, an outer surface and a length extending along a longitudinal axis from a first end of the wall to a second end of the wall. The wall can be configured to permit infrared radiation to pass through the wall from the inner space to the outer surface with the resistance element extending within the inner space. In some cases, a shield extends over the outer surface of the tube with the shield configured to prevent microwaves employed in a microwave oven from being incident on the tube. The shield can define an outer surface of the heating element. In some embodiments, the shield has a first portion that extends along the length of the tube and is configured to block passage of infrared radiation emitted by the circuit, and a second portion that extends along at least a portion of the length of the tube and is configured to permit infrared radiation emitted by the circuit to pass through the shield. A grounding element can be configured to electrically couple with the shield and with a cavity wall of an oven, e.g., to electrically connect the cavity wall with the shield.

In some embodiments, the support is a first support that engages with the first end of the resistance element, and the heating element can include a second support that includes a slot to receive the second end of the resistance element with the support configured to engage the resistance element to permit the second end to move within the slot due to thermal expansion or contraction of the resistance element. In some cases, the resistance element is supported only by the first and second supports, e.g., the resistance element can be suspended between the first and second supports.

In some embodiments, an oven includes a cooking cavity defined by one or more cavity walls configured to receive food to be heated and having a food support at which food to be heated is supported. A plurality of radiant energy heating elements can be positioned in the cooking cavity with the heating elements each including a resistance element extending between first and second ends that has a circuit configured to emit infrared radiation and visible light in response to an electrical current in the resistance element. A controller can be configured to control operation of the heating elements in a cooking mode having first and second phases. In a first phase, while a first heating element is operated to emit infrared radiation and visible light, a second heating element can be operated to emit infrared radiation but no visible light. In a second phase the first heating element can be operated to stop emitting visible light and the second heating element can be operated to emit infrared radiation and visible light such that the second heating element begins emitting visible light when the first heating element stops emitting visible light. The first and second control phases can be employed in different cooking modes, such as a virtual rotisserie mode in which heating element are sequentially or otherwise operated to emit infrared radiation in two or more separate time periods.

In some embodiments, the heating elements can be configured to emit infrared radiation and visible light when the resistance element is above a threshold temperature and to emit infrared radiation and no visible light when the resistance element is below the threshold temperature. In some cases, in the first phase the controller operates the second heating element such that the resistance element is within 10% of the threshold temperature before the second phase is initiated. In this way, the second heating element can be ready to emit visible light in a relatively short period of time because the temperature of the element can be increased to or above the threshold temperature in a short period of time.

In some cases, the plurality of heating elements are positioned in the cooking cavity such that at least two upper heating elements are positioned above the food support and at least two lower heating elements are positioned below the food support. A first upper heating element can be positioned nearer a front of the cooking cavity than a second upper heating element, and a first lower heating element can be positioned nearer a front of the cooking cavity than a second lower heating element. In some embodiments, the first phase includes, while a first upper heating element is operated to emit infrared radiation and visible light, a second upper heating element is operated to emit infrared radiation but no visible light. The second phase can include stopping the first upper heating element from emitting visible light and the second upper heating element is operated to emit infrared radiation and visible light such that the second upper heating element begins emitting visible light when the first upper heating element stops emitting visible light.

In some cases, the first phase includes, while an upper heating element is operated to emit infrared radiation and visible light, a lower heating element is operated to emit infrared radiation but no visible light, and the second phase includes stopping the upper heating element from emitting visible light and the lower heating element is operated to emit infrared radiation and visible light such that the lower heating element begins emitting visible light when the upper heating element stops emitting visible light.

In some embodiments, the cooking mode is a virtual rotisserie mode in which the plurality of heating elements are each sequentially operated to emit infrared radiation and visible light and the first and second phases are used to switch between operation of the heating elements.

In some embodiments, the oven can be configured to include any of the features described above or otherwise herein. For example, the oven can include a microwave supply including a magnetron and a waveguide to provide microwaves into the cooking cavity to heat food in the cavity, and the oven can be configured to simultaneously operate the magnetron and at least one of the plurality of the heating elements during a cooking operation. Similarly, the heating elements can be configured to include any of the features or combinations of such features described above or otherwise herein.

In some embodiments, a method of cooking can include providing a cooking cavity defined by one or more cavity walls and configured to receive food to be heated. In a first phase, a first heating element positioned in the cooking cavity can be operated to emit infrared radiation and visible light. Also in the first phase, a second heating element can be operated to emit infrared radiation and no visible light while the first heating element is emitting infrared radiation and visible light. In a second phase, the first heating element can be operated to stop emitting visible light and the second heating element can be operated to emit infrared radiation and visible light such that the second heating element begins emitting visible light when the first heating element stops emitting visible light.

In some cases, the first and second heating elements can be configured to emit infrared radiation and visible light when a resistance element is above a threshold temperature and to emit infrared radiation and no visible light when the resistance element is below the threshold temperature. In the first phase, the second heating element can be operated to emit infrared radiation and no visible light by operating the second heating element such that the resistance element is within 10% of the threshold temperature.

In some cases, the first heating element can be a first upper heating element positioned above a food support in the cooking cavity, and the second heating element can be a second upper heating element positioned above a food support in the cooking cavity. In some cases, the first heating element can be a first upper heating element positioned above a food support in the cooking cavity, and the second heating element can be a second lower heating element positioned below a food support in the cooking cavity. In some embodiments, the method can include operating a plurality of heating elements to sequentially emit infrared radiation and visible light in a virtual rotisserie mode, where operation of the first and second heating elements in the first and second phases is employed to switch between sequential operation of the heating elements. The method can include operating other components of the oven, such as a microwave or convection component, to heat food in the cooking cavity.

In some embodiments, an oven includes a cooking cavity defined by one or more cavity walls configured to receive food to be heated. A radiant energy heating element can be positioned in the cooking cavity with the heating element including a resistance element extending between first and second ends and including a circuit configured to emit infrared radiation in response to an electrical current in the resistance element. A convection element can include a fan and duct to move air into the cooking cavity. The duct can have one or more ports positioned adjacent the heating element and configured to output moving air that is directed at and impacts the heating element. For example, the one or more ports and the heating element can be configured such that air flow from the one or more ports is diffused by impact with the heating element.

In some cases, the one or more ports include openings arranged in a cavity wall and are configured along a line that extends along a length of the heating element. For example, the cavity wall can be a top wall of the cooking cavity and the heating element can be arranged to extend in a direction parallel to and below a plane of the top wall. The cooking cavity can include a food support in the cooking cavity that is positioned below the top wall and the heating element. In some cases, the heating element can be located between the one or more ports and the food support, and the one or more ports can be configured to direct the air downwardly toward the food support. In some embodiments, the duct includes an intake port to draw air from the cooking cavity into the duct with the intake port being located at a side wall or bottom wall of the cooking cavity. In some cases, the convection element includes a heater configured to heat air in the duct, e.g., the heater can be an electric resistance heater positioned in the duct downstream of the fan.

In some cases, the oven includes a microwave supply including a magnetron and a waveguide to provide microwaves into the cooking cavity to heat food in the cavity. The oven can be configured to simultaneously operate the magnetron, the fan and the heating element(s) during a cooking operation.

The radiant energy heating element can have any of the features described above or otherwise herein, including any combination of such features that are not mutually exclusive. As merely one example, the heating element can include a shield that extends around the resistance element with the shield configured to permit infrared radiation to pass through at least a portion of the shield and to prevent microwaves from being incident on the resistance element. A portion of the shield configured to block infrared radiation can be configured to be impacted by air exiting the one or more ports.

In some embodiments, a method of cooking includes providing a cooking cavity defined by one or more cavity walls and configured to receive food to be heated. Infrared radiation can be emitted from a heating element positioned in the cooking cavity, and a flow of air can be directed from a port adjacent the heating element such that the flow of air impacts the heating element. In some cases, the flow of air can be diffused by impact with the heating element. In some embodiments, the flow of air can be emitted from openings arranged in a cavity wall along a line that extends along a length of the heating element. In some examples, the cavity wall can be a top wall of the cooking cavity and the heating element can be arranged to extend in a direction parallel to and below a plane of the top wall.

In some embodiments, the flow of air can be emitted from the openings in a direction toward a food support in the cooking cavity, and the heating element can be located between the one or more ports and the food support. In some cases, air can be drawn into an intake port fluidly connected to the port, and the intake port can be located at a side wall or bottom wall of the cooking cavity. In some examples, the air can be heated before the air is emitted from the port.

In some examples, microwaves can be provided into the cooking cavity to heat food in the cavity during a cooking operation while the heating element emits infrared radiation in the cooking cavity. Microwaves can be prevented from being incident on the heating element by a shield that extends around the heating element with the shield configured to permit infrared radiation to pass through at least a portion of the shield and to prevent microwaves from being incident on the heating element. As noted above, the infrared heating element can be configured to have any features or combinations of features described herein. As an example, air flow from the one or more ports can be blocked from impacting a quartz tube of a heating element by using a first portion of a shield positioned between the tube and the one or more ports. However, infrared radiation can be permitted to pass through a second portion of the shield opposite the first portion.

As discussed herein, visible light can be in a wavelength range of 570 to 800 nanometers and be emitted as a result of the heating element operating in such a way as to emit infrared at a desired wavelength range and radiative flux to heat food items. Thus, the visible light can confirm to a user that a food item is being cooked or otherwise heated in a particular way, e.g., rapidly, uniformly and without drying.

A variety of additional aspects will be set forth in the description that follows. The aspects can relate to individual features and to combination of features. It is to be understood that both the foregoing general description and the following detailed description are exemplary and explanatory only and are not restrictive of the broad inventive concepts upon which the embodiments disclosed herein are based. To the extent various aspects are not mutually exclusive, such aspects can be combined together or employed separately in any suitable way in any suitable embodiment.

### BRIEF DESCRIPTION OF THE DRAWINGS

FIG. 1 is an upper left, front perspective view of a cooking appliance arranged as an oven in an illustrative embodiment.

FIG. 2 is a lower right, front perspective view of the FIG. 1 oven.

FIG. 3 is an upper right, front perspective view of the FIG. 1 oven with portions of the housing removed.

FIG. 4 is an upper left rear perspective view of the FIG. 1 oven with portions of the housing removed.

FIG. 5 is an upper left, front perspective view of the FIG. 1 oven with portions of the microwave supply and convection element removed.

FIG. 6 is a lower left, front perspective cross sectional view along the line 6-6 in FIG. 5.

FIG. 7 is an upper perspective view of heating element configurations in an illustrative embodiment.

FIG. 8 is a lower perspective view of the FIG. 7 heating element configurations.

FIG. 9 is an upper closeup view of the FIGS. 7 and 8 heating element configurations.

FIG. 10 is a lower close up view of the FIGS. 7 and 8 heating element configurations.

FIGS. 11 and 12 are enlarged perspective views of the FIGS. 7 and 8 heating element configurations in a partially assembled state.

### DETAILED DESCRIPTION

Various embodiments will be described in detail with reference to the drawings, wherein like reference numerals represent like parts and assemblies. Reference to various embodiments does not limit the scope of the claims. Additionally, any examples set forth in this specification are not intended to be limiting and merely set forth some of the many possible embodiments for the claims.

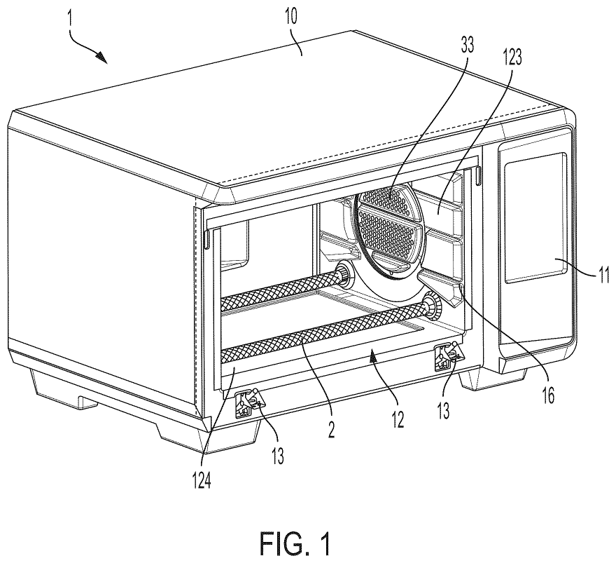

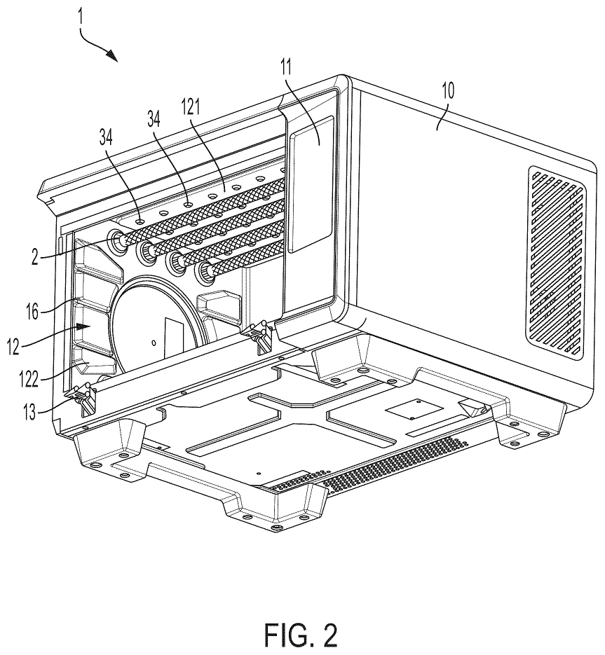

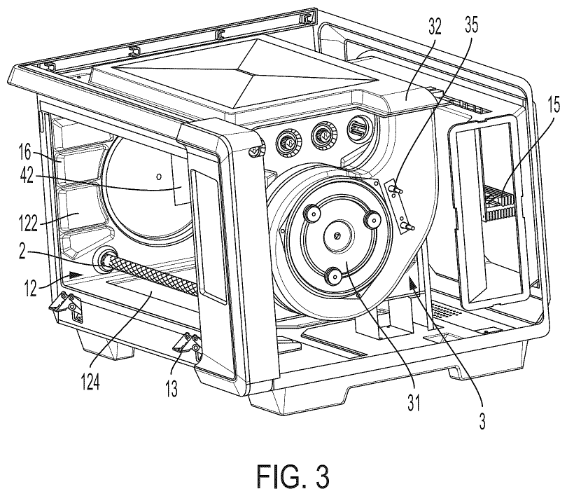

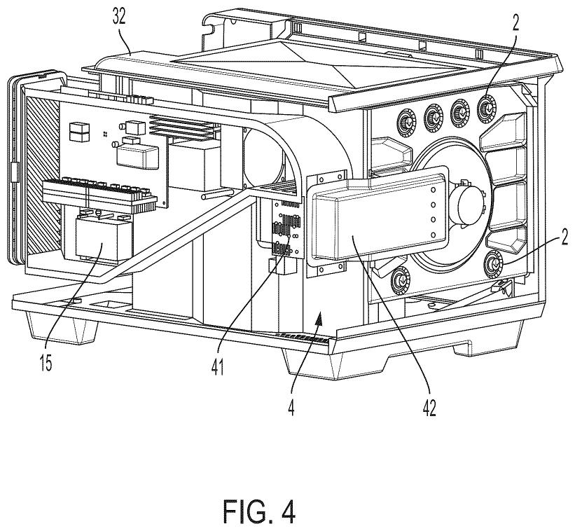

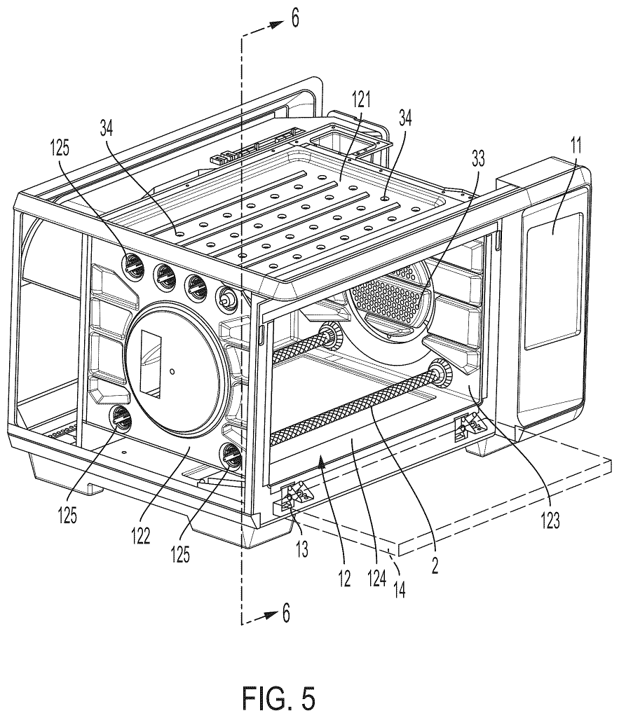

FIGS. 1 and 2 show perspective views of an illustrative cooking appliance 1, e.g., an oven, that includes a housing 10 which at least partially encloses a cooking cavity 12 defined by one or more cavity walls 121-124. In use, food is placed within the cooking cavity 12 on a food support 16 and is heated by the oven 1, e.g., by one or more heating elements 2. A user can interact with a user interface 11 to provide instructions to the oven 1 for cooking (e.g., cooking time, temperature, mode, food type, etc.) and/or to receive information from the oven 1 (e.g., cooking time remaining, current temperature, cooking mode, etc.). In some embodiments, the oven 1 can include other or additional components to heat food in the cavity 12, such as a convection element 3 (e.g., see FIG. 3) and/or microwave source 4 (e.g., see FIG. 4) which are discussed in more detail below. In some examples, the food support 16 includes one or more grooves or other features on side walls 122, 123 of the cavity 12 that are configured to engage with and support a food rack, tray, etc. (not shown for clarity) of the food support 16. For example, side portions of a food rack or tray can be engaged with the grooves at the side walls 122, 123 so as to be suspended in the cooking cavity 12. Other arrangements for a food support 16 are possible, such as a turntable support as is commonly found in microwave ovens, a platen on the bottom wall 124 of the cavity 12, etc. The oven 1 also includes a door 14 or other component (see FIG. 5) that can be opened to permit a user access to the cavity 12 to place food in and/or remove food, and can be closed to enclose the food in the cavity 12. In FIGS. 1 and 2, the door is removed for clarity, but hinges 13 are shown to which a door 14 can be mounted. In some embodiments, the door 14 can pivot about a horizontal axis at a lower front side of the cavity 12, e.g., so the door can pivot downwardly to open. In other examples, the door 14 can open about a vertical hinge or other configuration. The door 14 and cavity walls 121-124 can be arranged to block microwaves from exiting the cavity and/or to help retain heat and/or gases in the cavity 12. For example, the door 14 and/or cavity walls 121-124 can include conductive metal panels and/or mesh configured to prevent the passage of microwaves from escaping the cavity 12.

In some embodiments, the oven 1 includes one or more heating elements 2 that emit infrared radiation in the cooking cavity 12. In FIGS. 1 and 2, two heating elements 2 are located at a bottom of the cooking cavity 12 below the food support 16 and four heating elements 2 are located at a top of the cavity 12 above the food support 16. However, other arrangements are possible with any suitable number of heating elements 2 at top, bottom, rear wall, side wall, or door locations of the cooking cavity 12. In some cases, the heating elements 2 can be located entirely in the cavity 12, e.g., surrounded by air in the cavity 12 and spaced from an adjacent wall. Thus, an entire outer surface of the heating elements 2 can be exposed to microwaves in the cavity 12. Infrared radiation emitted by the heating elements 2 can be directed, at least in part, to food in the cavity 12 and heat the food.

In some embodiments, the heating elements 2 can be controlled by a controller of the oven 1 to operate in a virtual rotisserie mode. In a conventional rotisserie, food is rotated or otherwise moved while in a cooking cavity and exposed to a stationary heat source. With a virtual rotisserie mode, the food need not be moved in the cavity 12, but instead heating elements or other heat sources can be moved or operated such that heat is emitted from different locations at different times relative to the food in the cavity 12. As an example, the heating elements 2 in the oven 2 of FIGS. 1 and 2 can be operated so that a first set of one or more heating elements 2 are energized to emit infrared radiation, and then subsequently another set of heating elements 2 are energized, and so on. This sequential operation of sets of heating elements 2 can mimic movement of food in the cavity 12. In some embodiments, a first heating element 2 can be turned on or otherwise operated to emit infrared radiation, and after a period of time the first heating element 2 can be turned off and a second heating element 2 turned on. Then, the second heating element 2 can be turned off and a third heating element 2 turned on, and so on. Using the oven of FIGS. 1 and 2 as an example, a sequence of heating element 2 activation can be controlled to provide a simulation of rotating food, e.g., by activating a first heating element 2 at the top front of the cavity 12, followed by a second heating element 2 at the top of the cavity 12 immediately behind the first heating element 2, followed by third heating element 2 immediately behind the second heating element 2, followed by a fourth heating element 2 immediately behind the third heating element 2, followed by a fifth heating element 2 at the bottom rear of the cavity 12, followed by a sixth heating element 2 at the bottom front of the cavity 12, followed by the first heating element 2, and so on. The heating elements 2 need not be operated one at a time, but rather sets of any two or more heating elements can be turned on during any step or phase in the control cycle.

In some embodiments, it may be desirable to not only operate the heating elements 2 in a multi-phase cyclical or other sequence, but also to provide visible light output from the heating elements 2 so a user can see that the cooking sequence is being performed. Infrared heating elements emit infrared light which is generally not in the visible spectrum and so a user cannot always see that a heating element is operating. By having heating elements 2 emit visible light as well as infrared light, a user can see that the heating element 2 is operating. Thus, for example, each heating element 2 that is energized may emit visible light in addition to infrared radiation during at least a portion of its operation. Also, in some embodiments, it may be desirable when operating heating elements in a sequence (e.g., in which one set of heating elements 2 is operated followed by another set, and so on) to have a first deenergized set of heating elements 2 stop emitting visible light at about the same time as a second energized set of heating elements 2 begins emitting visible light. This can give the appearance to a user that when the first set of heating elements 2 stops operation, the second set of heating elements 2 immediately starts its heating operation. Note as well that a same heating element 2 can be turned on during two or more sequential steps in the cycle.

In some cases, radiant energy heating elements 2 do not immediately emit visible light upon activation, e.g., when the heating element 2 is turned on or otherwise provided with electrical energy while in a relatively cool state. That is, some heating elements 2 begin to emit infrared radiation before emitting visible light because the heating element 2 must heat to a threshold temperature to emit visible light, and the threshold temperature for emitting visible light can be higher than that for emitting infrared radiation. As a result, if a first heating element 2 is deenergized or otherwise has its power reduced at the same time that a second heating element 2 is energized, the first heating element 2 may stop emitting visible light long before the second heating element 2 begins emitting visible light because of the time needed for the second element 2 to sufficiently heat to emit visible light. In some embodiments, heating elements 2 in an oven can be controlled so that a first heating element 2 will stop emitting visible light at the same time that a second heating element 2 begins emitting visible light. This can be done by preheating or energizing the second heating element 2 so that the second heating element 2 emits infrared radiation but not visible light at a time while the first heating element 2 is still emitting visible light. This way, when the first heating element 2 has its power reduced, the second heating element 2 will be ready to relatively quickly heat to a point where it emits visible light as the first heating element 2 stops emitting visible light. In some cases, the second heating element 2 can be energized such that the second heating element 2 is near but below a threshold temperature at which the second heating element 2 emits visible light before the first heating element 2 is deenergized or stops emitting visible light. This way, the second heating element 2 need only increase its temperature a relatively small amount in a relatively small amount of time to begin emitting visible light.

In some embodiments, a controller of the oven can be configured to control operation of the heating elements in a cooking mode having first and second phases. In a first phase, while a first heating element is operated to emit infrared radiation and visible light, a second heating element is operated to emit infrared radiation but no visible light. This can be considered a pre-heating or preparation phase for the second heating element that gets the second heating element ready to emit visible light in a relatively short period of time. In a second phase, the first heating element is operated to stop emitting visible light, e.g., by interrupting or otherwise reducing power to the heating element, and the second heating element is operated (e.g., by increasing power to the heating element) to emit infrared radiation and visible light such that the second heating element begins emitting visible light when the first heating element stops emitting visible light. The timing required to achieve visible light emission can be effected in different ways and may depend on the heating elements. For example, in some cases, the second heating element can be energized with a fixed power level and the power to the first heating element can be interrupted or otherwise reduced at a later time so that the first heating element stops emitting visible light when the second heating element starts emitting visible light. In other cases, the second heating element can be operated at a relatively low power level, e.g., one at which the second heating element reaches a temperature near but below the threshold temperature at which the heating element emits visible light (e.g., a temperature within about 10% of the threshold temperature), and then operated at a higher power level at about the time the power to the first heating element is reduced. Such power level adjustments can be made using different control arrangements, such as adjusting a voltage and/or current of electrical power applied to the heating elements, e.g., using a pulse width modulation or other control arrangement.

As will be understood, the two phase operation for switching between heating elements or sets of heating elements can be employed in a virtual rotisserie cooking mode or any other cooking mode. Thus, the two phase control can be employed when heating elements are sequentially operated to emit infrared radiation and visible light and the first and second phases are used to switch between operation of the heating elements. Note as well that food can be heated using other heat sources in the oven in addition to infrared radiation from the heating elements 2, such as microwave energy, a heated air or convection heating system, etc.

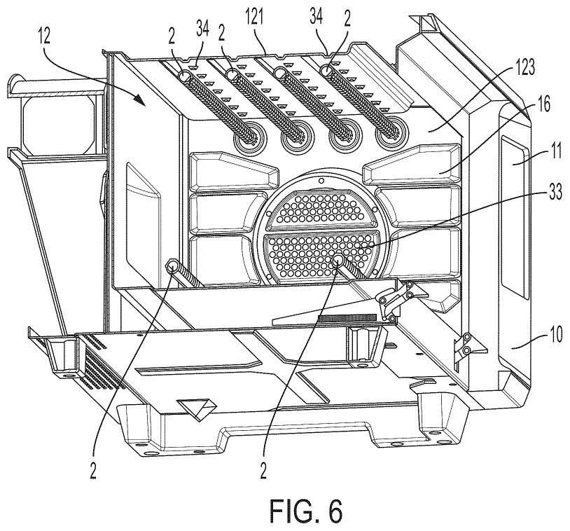

As noted above, in some embodiments the oven 1 can include a convection element 3 that can heat air and move the heated air around the cavity, e.g., to help cook food in the cavity. As can be seen in FIG. 3, the oven 1 can include a convection element 3 that includes a fan 31 and duct 32 to move air into the cooking cavity 12. The duct 32 can have an inlet port 33 at a side wall 123 as shown in FIG. 1 and/or at the bottom wall 124 to draw air from the cavity 12 into the duct 32. The fan 31 can move air through the duct 32, e.g., into a plenum or other portion of the duct 32 above the top wall 121 of the cavity 12 so the air can be directed back into the cavity 12. In some cases, the convection element 3 can include a heater 33 such as an electrical resistance heater that heats air as it moves through the duct 32. In some embodiments, the duct 32 can have one or more exhaust ports 34 each positioned adjacent a heating element 2 in the cavity 12 and configured to output moving air that is directed at and impacts the heating element 2. For example, as can be seen in FIG. 5, air can flow in the duct 32 into a plenum or space over a plurality of exhaust ports 34. As can be seen in FIGS. 2 and 6, air can exit the exhaust ports 34 to be directed at a corresponding heating element 2 below the ports 34. The ports 34 and the heating elements 2 can be configured such that air flow from the ports 34 is diffused by impact with the heating element 2. This can help prevent air from the ports 34 flowing directly into contact with food in the cavity 12, and instead create turbulence, breakup the flow of air or otherwise diffuse the flow of air from the ports 34.

In some cases, the ports 34 include openings arranged in a cavity wall, such as the top wall 121, and configured along a line that extends along a length of a heating element 2. In some cases, the heating elements 2 can be arranged to extend in a direction parallel to and below a plane of the top wall 121, and the food support 16 can be positioned below the top wall 121 and the heating element 2. Thus, in some cases, the heating element 2 can be located between one or more of the ports 34 and the food support 16, e.g., where the ports are configured to direct air downwardly toward the food support 16. Other arrangements for the ports 34 and heating elements 2 can be employed in which air output from the ports 34 is diffused or otherwise disrupted in flow by the heating elements 2. For example, ports 34 can be arranged at a side wall 122, 123 and/or bottom wall 124, and heating elements 2 arranged to extend along a side wall 122, 123 and/or bottom wall 124 (as shown in FIGS. 1 and 3). Thus, configurations in which ports exhaust air directed at a heating element are not limited to employment at a top wall of a cooking cavity 12. The ports 34 can have any suitable size and/or shape, e.g., circular, oval (optionally extending along a length of a corresponding heating element), etc.

In some embodiments, the oven can include a microwave supply to provide microwave energy into the cooking cavity to heat food. As with other cooking energy sources, the microwave supply can be used alone, or in any suitable combination with other sources, such as one or more heating elements and/or a convection element. As can be seen in FIG. 4, the microwave supply 4 can include a magnetron 41 to generate and emit suitable microwave energy and a waveguide 42 to conduct the microwave energy into the cooking cavity 12. The magnetron 41 and other components of the oven (such as the fan 31, heating elements 2, user interface 11, etc.) can be controlled by a controller 15 arranged to perform any suitable input/output and other control functions. The walls 121-124 and door 14 (see FIG. 5) that define the cooking cavity 12 can be configured to help keep microwave energy in the cavity 12 so the microwave energy is not emitted from the cavity 12 or emitted at relatively low levels. Typically, this is done by employing metal wall elements, whether perforated or not, at the walls 121-124 and/or door 14.

In some embodiments, heating elements 2 are exposed within the cavity 12 to microwave energy, e.g., the heating elements 2 can be positioned within the cavity defined by the walls 121-124 so that air in the cavity can flow around the heating elements 2. This is in contrast to ovens that employ both microwave and radiant heating elements in which the heating elements are positioned in a cavity wall recess behind a microwave blocking panel or other element. Since the heating elements 2 are in some embodiments exposed to microwave energy, e.g., at portions along their entire length in the cavity 12, steps must be taken to help prevent microwave energy from exiting the cavity 12 via the heating elements 2. In some prior ovens, a choke or other element is arranged outside of the cavity 12 over the ends of the heating elements 2 to help contain microwaves in the cavity. However, this approach can be cumbersome and provide less than desired microwave containment. In some embodiments, heating elements exposed in a cooking cavity can have a shield that extends around a resistance element of the heating element that emits infrared radiation. The shield can define an outer surface of the heating element and be configured to permit infrared radiation, e.g., emitted by the resistance element, to pass through at least a portion of the shield and to prevent microwaves from being incident on the resistance element. As a result, the shield can prevent microwaves from exiting the cavity via the resistance element or other portions of the heating element within the shield, while permitting infrared energy to freely pass through at least portions of the shield for cooking purposes. In some cases, the shield can provide physical protection for the heating element components within the shield, such as a quartz tube in which the resistance element is located. Thus, heating elements with a shield can in some cases be employed in ovens that do not include a microwave supply.

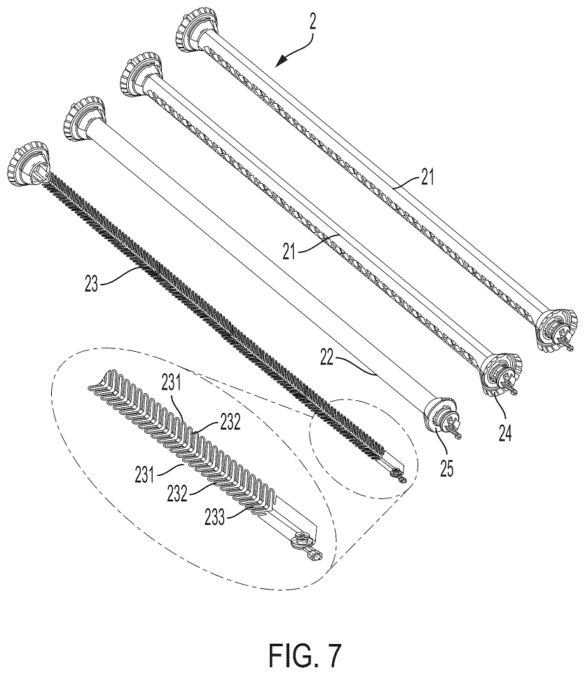

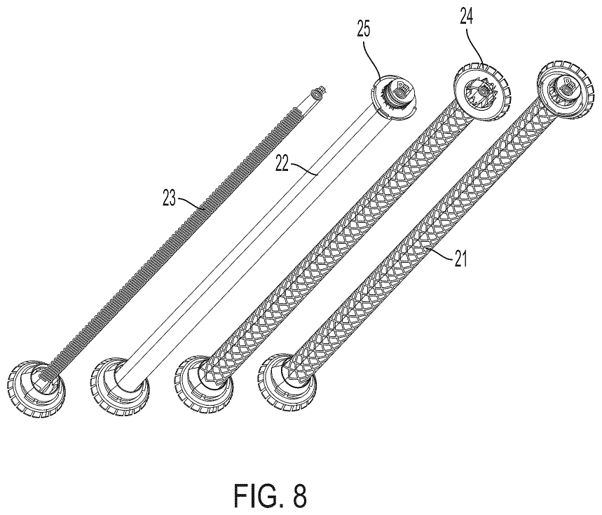

FIGS. 7 and 8 show upper and lower perspective views of illustrative heating elements 2 in different levels of assembly. In some embodiments, a heating element 2 includes a resistance element 23 that extends between first and second ends and includes a circuit configured to emit infrared radiation in response to an electrical current in the resistance element. For example, control circuitry can be connected to the first and second ends of the resistance element so a voltage can be applied across the first and second ends and cause a current to flow through the resistance element 23. This current can cause the circuit of the resistance element 23 to heat and emit infrared radiation. In some cases, the resistance element 23 can be configured to emit visible light as well, e.g., when one or more portions of the resistance element 23 is above a threshold temperature. The circuit of the resistance element that emits infrared radiation can be configured in different ways. In some embodiments, the circuit includes a metal or other conductive portion that has a serpentine shape formed by bends 231 that are linked by legs 232 to form a continuous “S” shape. The legs 232 can be arranged to extend perpendicular to the length or longitudinal axis of the resistance element 23 as shown in FIG. 7, or at other angles. In some embodiments and as can be seen in FIG. 7, the circuit includes two parallel portions or sides connected at a joint 233. In some cases, the two sides of the circuit can each be planar and joined at one edge of the respective planes at the joint 233. In some embodiments, each of the two sides of the circuit can have a serpentine shape that includes a continuous “S” shape that extends along the length of the resistance element 23. The serpentine shape can be formed by bends 231 that are connected by legs 232 that extend between respective bends 231. Inner bends 231 of the two parallel sides are connected at the joint 233, and are connected by legs 232 to outer bends 231 that form outer edges of the two portions of the circuit. Thus, current in each of the two sides can flow outwardly from the joint 233 through a leg 231 to an outer bend 231 and then inwardly via another leg 231 to an inner bend 231 and the joint 233, and so on. This arrangement can help balance current flow in the two parallel sides of the circuit and/or permit parts of the two sides to continue to operate to emit infrared radiation if a leg 232 or outer bend 231 is damaged such that electrical continuity is lost. The shape of the circuit can be made in different ways, such as by stamping or machining a flat sheet of metal or other conductive material so as to form openings that define the bends 231 and legs 232, e.g., to form a repeating pattern of oval or other closed loop forms so that adjacent loops are joined at central areas of the loops at the joint 233.

In some embodiments, a portion of the circuit of the resistance element 23 defines a convex shape, e.g., that extends along the length of the resistance element 23. This configuration can provide benefits such as providing physical strength and/or stiffness to the circuit (e.g., by increasing the moment of inertia of the circuit) and/or by enabling the resistance element to emit a greater amount of infrared radiation in a first direction than in a second opposite direction. For example, the resistance element 23 can define a V-shape in cross section to the length or longitudinal axis of the resistance element 23 as in FIG. 7. Other convex shapes are possible, however, such as U-, W-, semi-circular, irregular or other shapes. In some embodiments, the convex shape can extend a distance between the first and second ends of the resistance element 23 that is at least 20%, at least 50%, at least 75%, and/or at least 90% of the length of the resistance element 23. In some cases, the circuit can have a width in a direction perpendicular to the longitudinal axis (e.g., a distance between outer bends 231), and the convex shape can extend a distance along the longitudinal axis that is greater than the width. In some embodiments, the convex shape can have a width in a direction perpendicular to the longitudinal axis that is at least 90% of the width of the circuit, e.g., in FIG. 7 the convex shape has a width that is 100% of the width of the circuit. In some cases, the circuit can define a concave shape that extends between the first and second ends and that is opposed to the convex shape. Thus, for example, the convex shape can face in a first direction and the concave shape can face in a second direction opposite to the first direction. In some cases, the circuit can be configured to emit a greater amount of infrared radiation in the first direction than in the second direction. For example, the circuit can be configured to emit 20% to 30% more infrared radiation in the first direction than in the second direction. This feature can provide for more efficient use of energy in heating food in a cooking cavity 12. For example, the heating elements 2 can be positioned to extend along a wall of the cavity 12, e.g., a top wall 121 or bottom wall 124, and the heating elements 2 can be configured so that the convex shape faces toward the food support 16. This can enable the heating elements 2 to provide a relatively higher level of radiant energy toward the food than otherwise. In some embodiments, however, the convex shape need not face the food support 16, but rather may be employed to help provide physical support to the resistance element 23. For example, a resistance element 23 having a V-shape may be oriented so the convex shape (or bottom of the V) faces downwardly regardless of where the heating element 2 is located in the cavity 12. This can help prevent the resistance element 23 from sagging or bending downwardly during operation because this orientation can provide increased strength as compared to other orientations.

In some embodiments, a portion of the circuit that defines the convex shape includes a first planar portion arranged at an angle relative to a second planar portion. For example, a first portion having a set of bends 231 and legs 232 on one side of the joint 233 may be arranged in a first plane, and a second portion having a set of bends 231 and legs 232 on the other side of the joint 233 may be arranged in a second plane at an angle to the first plane. The first and second planes meet at the joint 233 and can be arranged at an angle to each other, e.g., to define a V-shape. The first portion of the circuit on the first side of the joint 233 and the second portion on the second side of the joint 233 can be opposed to each other and can each have a serpentine shape. For example, current can flow through a tortuous path including the legs 232 and bends 231 on the first side of the joint 233, and can flow another tortuous path through legs 232 and bends 231 on a second side of the joint 233.

In some embodiments, the heating elements 2 can have a tube 22 including a wall that defines an inner space in which the resistance element 23 is positioned and extends. The tube 22 can have an outer surface and a length extending along a longitudinal axis from a first end of the tube wall to a second end of the tube wall. The tube wall can be configured to permit infrared radiation to pass through the wall from the inner space to the outer surface and to a food support 16. In some cases, the tube can be a quartz tube or other material that is generally transparent to infrared radiation. The tube 22 can be electrically insulating, e.g., to help prevent the resistance element 23 from forming an electrical short circuit by contacting another conductive component.

In some cases, a shield 21 can extend over the outer surface of the tube 22, or over the resistance element 23 if no tube 22 is provided. The shield 21 can be configured to permit infrared radiation to pass through at least a portion of the shield and to prevent microwaves employed in a microwave oven from being incident on the tube 22 and/or the resistance element 23. As mentioned above, a resistance element can provide a path for microwaves to exit the cooking cavity because the resistance element is typically made of an electrically conductive material and is configured such that microwaves can be transmitted out of the cavity by the resistance element. However, by providing a shield 21 over the resistance element 23, microwaves can be prevented from contacting the resistance element 23. In addition, or alternately, the shield 21 can provide physical protection to the heating element 2, e.g., to help prevent contact with and/or damage to the resistance element 23 and/or the tube 22. In some cases, the shield 21 can completely surround the tube 22 and/or resistance element 23, e.g., the shield 21 can have a tubular shape that fits over the tubular shape of the tube and defines an outer surface of the heating element.

In some embodiments, the shield 21 can have a first portion that extends along a length of the resistance element 23 and is configured to block passage of infrared radiation emitted by the circuit, and a second portion that extends along at least a portion of the length of the resistance element and is configured to permit infrared radiation emitted by the circuit to pass through the shield 21. For example, as shown in FIGS. 7 and 8, the shield 21 can have a side that is solid (e.g., in the form of a partial cylindrical shell visible in FIG. 7) and that blocks infrared radiation and/or air flow, and another side or portion that has one or more openings (e.g., in the form of a mesh visible in FIG. 8) to permit infrared radiation to freely pass. In some cases, the first portion of the shield that blocks passage of infrared radiation can be positioned adjacent or opposite to a cavity wall, e.g., a solid portion of the shield 21 can be positioned opposite a top wall 121 of the cavity 12, and the second portion that permits infrared radiation to pass can be positioned to face the food support 16. This can help direct infrared radiation towards food in the cavity 12 and help prevent heating of the cavity walls. Also, if the resistance element 23 is capable of emitting a greater amount of infrared radiation in one direction than another, the second portion of the shield 21 that allows infrared radiation to pass can be aligned with the direction of greater infrared emission. For example, a convex part of the resistance element 23 can face toward the second portion of the shield 21. In some cases, despite having openings in the shield to permit infrared radiation to pass, the shield 21 can still prevent microwaves from contacting the tube 22 or resistance element 23. For example, the second portion can include a conductive component (e.g., a mesh or perforated metal plate) with a plurality of openings sized configured to permit infrared radiation to pass through the openings and to block the microwaves from passing through the openings. In some cases, the portion of the shield configured to permit infrared radiation to pass can be configured to permit 70 to 90% of infrared radiation emitted by the circuit to pass through the shield 21.

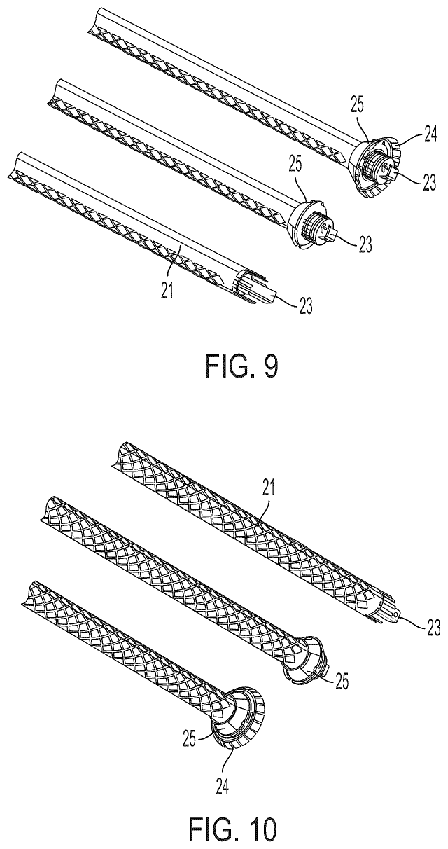

In conditions where a heating element 2 is exposed in a cooking cavity 12 to microwaves, e.g., the heating element 2 is spaced from walls of the cavity 12 so that microwaves can surround the heating element 2, the shield 21 can be electrically grounded to a cavity wall to help prevent microwaves from exiting the cavity 12 via the resistance element 23 or other parts of the heating element 2. In some cases, the heating element 2 includes grounding elements 24 to electrically connect opposite ends of the shield 21 to a respective cavity wall. In some embodiments, the grounding elements 24 are configured to fit or otherwise be received in a recess 125 of a cavity wall (see FIG. 5, for example) and thereby make electrical contact with the cavity wall. As an example, the recess 125 can be formed to have a cylindrical shape and the grounding elements 24 can fit within a corresponding recess 125 with a friction or interference fit. In some cases, the grounding elements 24 can provide mechanical or physical support for the heating element 2 on the cavity wall. As can be seen in FIGS. 9 and 10, the grounding elements 24 are assembled onto ends of a heating element 2 along with a support 25. For example, after a resistance element 23 is positioned within a tube 22 and a shield 21 is positioned over the tube 22, a support 25 can be fitted onto the end of the tube 22 and shield 21. Thereafter, a grounding element 24 can be fitted onto the support 25 and so as to make electrical contact with the shield 21.

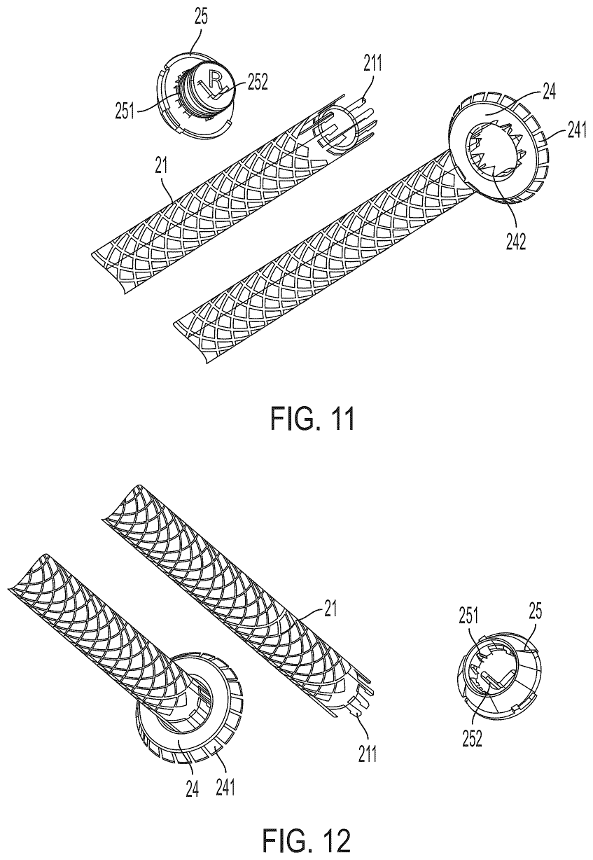

FIGS. 11 and 12 show close up views of the ends of the shield 21, the support 25 and the grounding elements 24. The ends of the shield 21 can includes multiple tabs 211, e.g., that extend from an end of the shield in a direction along the length of the shield 21 or its longitudinal axis. The support 25 includes multiple openings 251 that are configured to receive a respective tab 211 so that when the support 25 is mounted on the shield 21, the tabs 211 extend through the openings 251 and emerge from the opposite side of the support 25. The grounding elements 24 include a body (e.g., having a circular or an annular shape) having an opening that is sized to fit over the end of the shield 21 and the tabs 211. In some cases, a portion of the support 25 extends through the opening of the grounding element 24 as well. The grounding elements 24 include multiple shield contacts 242 that each form a tab, are flexible and extend from the body at the opening. The shield contacts 242 are configured to contact one or more tabs 211 of the shield 21 to electrically connect the grounding element 24 and the shield 21. The tabs 211 and/or the shield contacts 242 can be resilient so that the tabs 211 and contacts 242 contact each other with a spring or resilient bias to help maintain the physical and electrical connection between the tabs 211 and contacts 242. The contacts 242 can extend radially inwardly from the opening of the body of the grounding element 24 to help ensure proper contact with the tabs 211. The openings 251 of the support 25 can provide physical support to the tabs 211, e.g., to help maintain the tabs 211 in a suitable orientation and position to connect with the contacts 242. The grounding elements 24 also include cavity wall contacts 241 that extend from the body, e.g., in a radially outward direction from a periphery of the body. For example, the body can have a circular or annular shape and the contacts 241 can extend radially outwardly from the outer periphery of the circular or annular shape. The contacts 241 can be resilient, e.g., capable of deforming when inserted into a recess 125 of a cavity wall to as to make suitable electrical and physical contact with the recess 125. For example, the outer edges of the contacts 241 can define a circular shape that is larger than the size of a recess 125 into which the grounding element 24 is inserted. The contacts 241 can flex inwardly to be received into the recess 125 and maintain contact with the inner surface of the recess 125. Engagement of the grounding elements 24 at opposite ends of a heating element 2 can provide mechanical support for the heating element 2 as well as provide an electrical grounding for the shield 21. The grounding elements 24 can be formed from a metal sheet, e.g., stamped to form the body and contacts 241, 242.

As can be seen in FIGS. 11 and 12, the support 25 can include a slot 252 to receive an end of a resistance element 23. In some embodiments, the slot 252 can mimic the convex shape defined by the resistance element 23, e.g., a V-shape, and can help prevent the resistance element from rotating relative to the support 25 about the longitudinal axis of the heating element. In some cases, the slot 252 and end of the resistance element 23 can be configured so that the end of the resistance element can slide along its length in the slot 252, e.g., due to thermal expansion and/or contraction. This can help reduce stresses on the resistance element 23, support 25 and/or other parts of the heating element 2 due to temperature changes. The support 25 can be made of an electrically insulating material such as a polymer, ceramic or other. In some cases, the support 25 may provide the only physical support to the resistance element 23, e.g., which is suspended at its first and second ends. The first and second ends of the resistance element 23 can extend from the support 25 to allow an electrical connection to be made to control circuitry that provides electrical power to the heating element 2.

The controller 15, including the user interface 11, can include a programmed processor and/or other data processing device along with suitable software or other operating instructions that are executable by the data processing device, one or more memories (including non-transient storage media that can store software and/or other operating instructions), sensors, input/output interfaces, communication devices (e.g., including a transceiver, radio, gateway, interface, etc. suitably programmed or otherwise configured to communicate using any suitable wired or wireless protocol), buses or other links, a display, switches, relays, triacs, a battery or other power source or supply, or other components necessary to perform desired input/output, control or other functions. The user interface 11 can be arranged in any suitable way and include any suitable components to provide information to a user and/or receive information from a user, such as buttons, a touch screen, a voice command module (including a microphone to receive audio information from a user and suitable software to interpret the audio information as a voice command), a visual display, one or more indicator lights, a speaker, and so on.

The various embodiments described above are provided by way of illustration only and should not be construed to limit the claims attached hereto. Those skilled in the art will readily recognize various modifications and changes that may be made without following the example embodiments and applications illustrated and described herein, and without departing from the true spirit and scope of the following claims.

1. An electrical resistance heating element comprising:
a tube having a wall defining an inner space, an outer surface and having a length extending along a longitudinal axis from a first end of the wall to a second end of the wall, the wall being configured to permit infrared radiation to pass through the wall from the inner space to the outer surface;
a resistance element extending in the inner space between the first and second ends, the resistance element including a circuit configured to emit infrared radiation in response to an electrical current in the resistance element; and
a shield that extends over the outer surface of the tube, the shield configured to permit infrared radiation to pass through at least a portion of the shield and to prevent microwaves employed in a microwave oven from being incident on the tube.

2. The heating element of claim 1, wherein the shield has a tubular shape.

3. The heating element of claim 1, wherein shield completely surrounds the tube and extends over the first and second ends of the tube.

4. The heating element of claim 1, wherein the shield has a first portion that extends along the length of the tube and is configured to block passage of infrared radiation emitted by the circuit, and a second portion that extends along at least a portion of the length of the tube and is configured to permit infrared radiation emitted by the circuit to pass through the shield.

5. The heating element of claim 4, wherein the second portion includes a conductive component with a plurality of openings configured to permit infrared radiation to pass through the openings and to block the microwaves from passing through the openings.

6. The heating element of claim 4, wherein the circuit is configured to emit a greater amount of infrared radiation in a first direction than in a second direction that is opposite the first direction, and wherein the first direction extends through the second portion of the shield.

7. (canceled)

8. The heating element of claim 1, wherein the tube is a quartz tube.

9. The heating element of claim 1, wherein the shield is configured to protect the tube from physical impact.

10. The heating element of claim 1, wherein the shield is configured to be electrically grounded to a cavity wall of a microwave oven.

11. The heating element of claim 1, wherein the portion of the shield configured to permit infrared radiation to pass is configured to permit 70 to 90% of infrared radiation emitted by the circuit to pass through the shield.

12. The heating element of claim 1, wherein the portion of the shield includes a metal mesh including openings sized to block the microwaves.

13. A microwave oven, comprising:
a cooking cavity defined by one or more cavity walls configured to receive food to be heated;
a microwave supply including a magnetron configured to provide microwaves for introduction into the cooking cavity to heat food in the cavity; and
a radiant energy heating element positioned in the cooking cavity for exposure to microwaves in the cooking cavity, the heating element including:
a resistance element extending between first and second ends, the resistance element including a circuit configured to emit infrared radiation in response to an electrical current in the resistance element; and
a shield that extends around the resistance element, the shield configured to permit infrared radiation to pass through at least a portion of the shield and to prevent microwaves from being incident on the resistance element.

14. The oven of claim 13, wherein the heating element includes a tube having a wall defining an inner space, an outer surface and having a length extending along a longitudinal axis from a first end of the wall to a second end of the wall, the wall being configured to permit infrared radiation to pass through the wall from the inner space to the outer surface, wherein the resistance element is positioned in the inner space, and the shield extends over the outer surface of the tube.

15. The oven of claim 14, wherein shield completely surrounds the tube.

16. The oven of claim 13, wherein the shield has a tubular shape.

17. The oven of claim 13, wherein the shield has a first portion that extends along a length of the resistance element and is configured to block passage of infrared radiation emitted by the circuit, and a second portion that extends along at least a portion of the length of the resistance element and is configured to permit infrared radiation emitted by the circuit to pass through the shield.

18. The oven of claim 17, wherein the second portion includes a conductive component with a plurality of openings configured to permit infrared radiation to pass through the openings and to block the microwaves from passing through the openings.

19. The oven of claim 17, wherein the circuit is configured to emit a greater amount of infrared radiation in a first direction than in a second direction that is opposite the first direction, and wherein the first direction extends through the second portion of the shield.

20. (canceled)

21. The oven of claim 13, wherein the heating element includes a quartz tube positioned between the shield and the resistance element.

22. The oven of claim 21, wherein the shield is configured to protect the quartz tube from physical impact.

23. The oven of claim 13, wherein the shield is configured to be electrically grounded to a cavity wall of the cooking cavity.

24. The oven of claim 13, wherein the portion of the shield configured to permit infrared radiation to pass is configured to permit 70 to 90% of infrared radiation emitted by the circuit to pass through the shield.

25. The oven of claim 13, wherein the shield of the heating element extends through opposite cavity walls and includes grounding contacts positioned outside of the cavity to electrically connect opposite ends of the shield to a respective cavity wall.

26.-27. (canceled)

28. The oven of claim 13, wherein the shield is spaced from and extends along a cavity wall.
